(19) United States
(12) Patent Application Publication
(10) Pub. No.: US 2011/0167687 A1
(43) Pub. Date: Jul. 14, 2011

(54) METHODS AND SYSTEMS FOR PROVIDING WIND TURBINE ELECTRIC GENERATION WITH ADVERTISING, AND PRODUCTS THEREBY

(76) Inventor: Marvin Winkler, Laguna Hills, CA (US)

(21) Appl. No.: 13/070,417

(22) Filed: Mar. 23, 2011

Related U.S. Application Data
(62) Division of application No. 12/483,581, filed on Jun. 12, 2009.
(60) Provisional application No. 61/119,092, filed on Dec. 2, 2008.

(51) Int. Cl. G09F 19/02; F03D 9/00; F03D 11/00; H02K 15/00; H05K 13/00

(52) U.S. Cl. 40/440; 29/592.1

(57) ABSTRACT

Systems and methods for providing wind turbine electric generation with advertising or other image patterns for calling the attention of an individual. The wind turbine electric generation may include a wind rotor, a plurality of blades, an image and an electric generator. The image is displayed on at least two of the plurality of blades to generate a dynamic image effect with the rotation of the plurality of blades around a central axis of rotation. The electric generator is coupled to and driven by the wind rotor to generate electricity. The methods may include providing a wind turbine electric generation system and displaying an image on at least two of the plurality of blades to generate a dynamic image effect with the rotation of the plurality of blades around the central axis of rotation.

### RELATED APPLICATION

This application is a divisional of U.S. patent application Ser. No. 12/483,581, filed Jun. 12, 2009, which claims the benefit of and priority to U.S. Provisional Application Ser. No. 61/119,092, filed Dec. 2, 2008, the contents of which are incorporated by reference herein in their entirety.

### BACKGROUND

This disclosure relates generally to advertising. The disclosure more specifically relates to methods and systems for providing wind turbine electric generation with advertising, and products thereby.

### SUMMARY

Systems and methods for providing wind turbine electric generation with advertising or other image patterns for calling the attention of an individual, are disclosed. The wind turbine electric generation may include a wind rotor, a plurality of blades, an image and an electric generator. The wind rotor is responsive to an air stream and rotatable around a central axis of rotation. The plurality of blades are mounted to the wind rotor at a radial distance from the central axis of rotation. The image is displayed on at least two of the plurality of blades to generate a dynamic image effect with the rotation of the plurality of blades around a central axis of rotation. The electric generator is coupled to and driven by the wind rotor to generate electricity.

In one embodiment, the image may be displayed across two or more of the plurality of blades. The image may include an advertisement and/or a pattern for calling a consumer's attention to a product or service. The image may be displayed on to at least two of the plurality of blades by projecting a light projection beam thereon. In one embodiment, the wind turbine electric generation system may include an array of light bulbs coupled to the plurality of blades, and a processor configured to selectively turn on and off the array of light bulbs for displaying the image on at least two of the plurality of blades.

In one embodiment, a wind turbine for displaying an image is provided. The wind turbine includes a wind rotor, a plurality of blades, an array of light bulbs and a processor. The wind rotor is responsive to an air stream and rotatable around a central axis of rotation. The plurality of blades are mounted to the wind rotor at a radial distance from the central axis of rotation. The array of light sources are coupled to the plurality of blades, and the processor is configured to selectively turn on and off the array of light sources for displaying the image on at least two of the plurality of blades.

Methods for providing a dynamic image effect with a renewable energy apparatus are also provided. The method includes providing a wind turbine electric generation system and displaying an image on at least two of the plurality of blades to generate a dynamic image effect with the rotation of the plurality of blades around the central axis of rotation.

Many other features and embodiments of the present invention will be apparent from the accompanying drawings and from the following detailed description.

### DRAWINGS

The above-mentioned features and objects of the present disclosure will become more apparent with reference to the following description taken in conjunction with the accompanying drawings wherein like reference numerals denote like elements and in which:

FIG. 1 illustrates a three-dimensional view of a wind turbine, according to an embodiment of the present disclosure.

FIG. 2 illustrates a three-dimensional view of a wind turbine with two coaxially aligned blades, according to an embodiment of the present disclosure.

FIG. 3 illustrates a three-dimensional view of a wind turbine with three coaxially aligned blades, according to an embodiment of the present disclosure.

FIGS. 4A-4D illustrate different frame views of an image displayed on the wind turbine of FIG. 1, according to an embodiment of the present disclosure.

FIGS. 5A-5D illustrate different frame views of an image displayed on the wind turbine of FIG. 3, according to an embodiment of the present disclosure.

FIG. 6 illustrates the wind turbine of FIG. 1 with an image displayed on one or more blades using a projector, according to an embodiment of the present disclosure.

FIG. 7 illustrates the wind turbine of FIG. 1 with an image displayed on one or more blades using an array of LED lights, according to an embodiment of the present disclosure.

FIG. 8 illustrates an enlarged view of section 8 of FIG. 7, according to an embodiment of the present disclosure.

FIG. 9 illustrates an exemplary flowchart outlining a method for providing a dynamic image effect on a renewable energy apparatus, according to an embodiment of the present disclosure.

### DETAILED DESCRIPTION

In the description that follows, the present disclosure will be described in reference to one or more embodiments for displaying an image on a wind turbine's blades. The present disclosure, however, is not limited to any particular application nor is it limited by the examples described herein. The present disclosure, for example, may be used with any renewable energy product. Therefore, the description of the embodiments that follow are for purposes of illustration and not limitation.

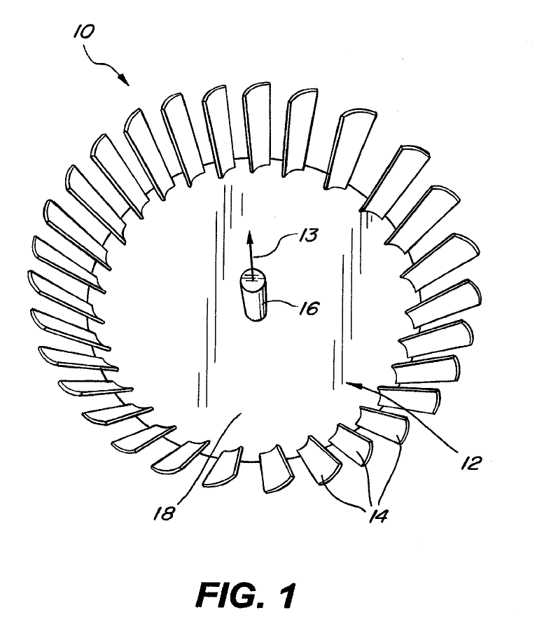

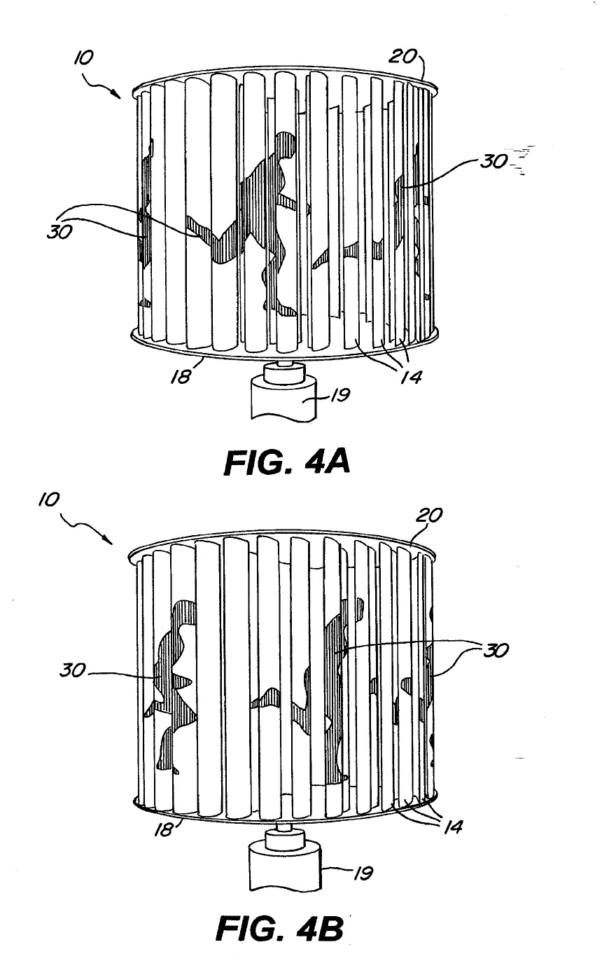

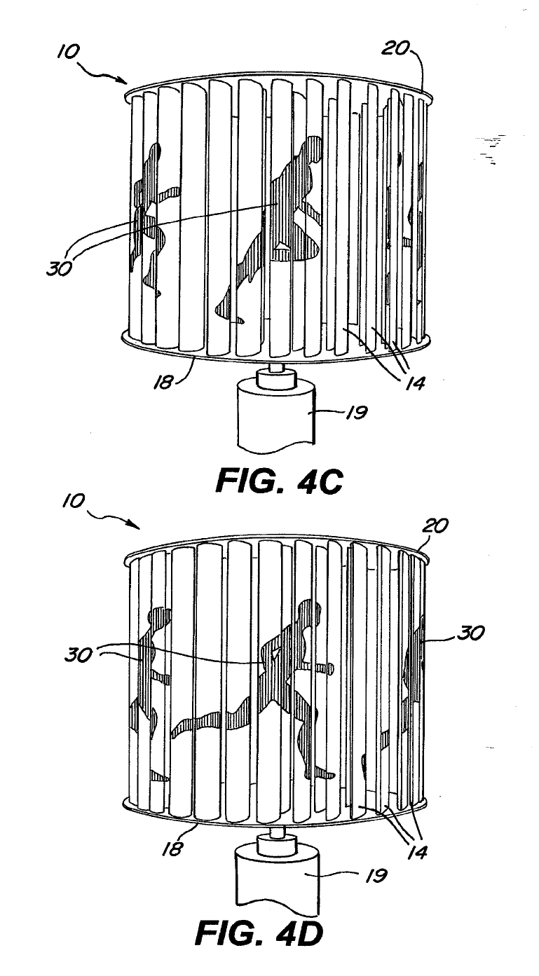

FIG. 1 illustrates a three-dimensional view of a wind turbine 10, according to an embodiment of the present disclosure. The wind turbine 10 may include a wind rotor 12 and a plurality of blades 14. The wind turbine 10 may have a central axis 13 which may be nominally upright. The wind rotor 12 may include a rotary tubular shaft 16, a lower plate 18 and an upper plate 20 (shown in FIGS. 4A-4D). The upper plate 20 was not illustrated in FIG. 1 to show the rotary tubular shaft 16, which otherwise cannot be seen in FIGS. 4A-4D.

The lower plate 18 and the upper plate 20 may be used to support a plurality of blades 14 connected to and extend axially between the plates 18, 20. The blades 14 may be aligned at a radial distance from the central axis of rotation 13. The driving force for this wind rotor 12 is the interaction of the blades 14 with an air stream. The blades 14 may all have an angular orientation around their own axis relative to the plates 18, 20.

The cross sectional shape of the blades 14 is arbitrary and may be made with a variety of shapes. The example given herein derives most of its net “lifting” force as the blade 14 moves through about a 30 degree arc relative to a nominal attack axis of the wind. The blades 14 may be set at any angle relative to their respective radius such that the blades 14 are properly aligned to exert the most effective force on the plates 18, within its most effective angle of attack. The blades 14 may be made from reinforced foam, fiber reinforced extrusions, or metal skins as desired. Lightweight plastic foams with a dip coated skin may also be used.

In one embodiment, the wind rotor 12 may be coupled to an electric generator 19 (shown in FIGS. 4A-4D). The wind rotor 12 may be used to drive the electric generator to generate electricity. As will be discussed in detail below, an image may be displayed on at least two of the blades 14 to generate a dynamic image effect with the rotation of the blades 14 around the central axis of rotation 13.

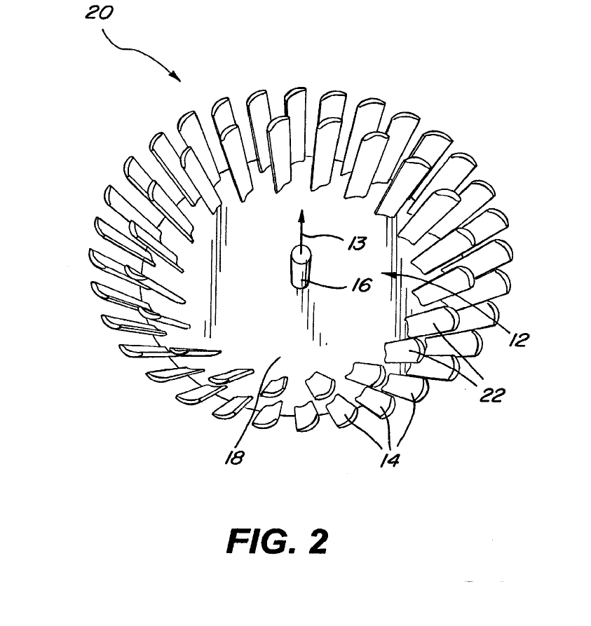

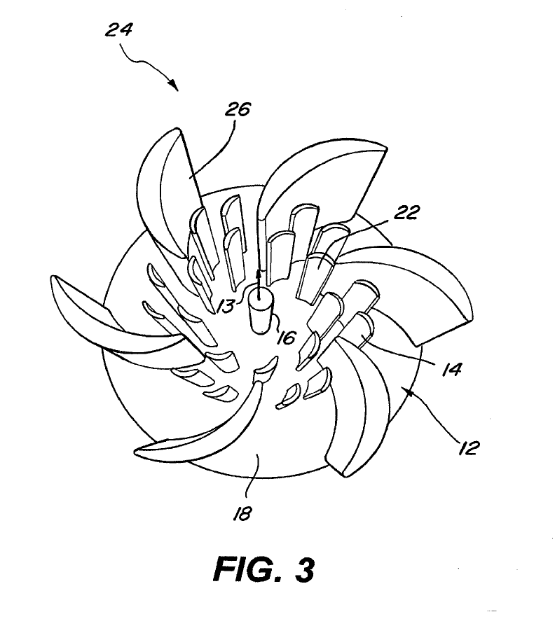

As is understood by a person skilled in the art, an image may be displayed on one or more coaxially aligned blades. FIG. 2 illustrates a three-dimensional view of a wind turbine 20 with two coaxially aligned blades 14 and 22, according to an embodiment of the present disclosure. The two coaxially aligned blades 14 and 22 may be equally spaced apart and at a certain radial distance from the central axis of rotation 13. In this embodiment, blades 22 are coaxially aligned on the inside of blades 14, and having the same blade dimensions. FIG. 3 illustrates a three-dimensional view of a wind turbine 24 with three coaxially aligned blades 14, 22 and 26, according to an embodiment of the present disclosure. As shown in FIG. 3, an outer coaxially aligned blade 26 with different blade dimensions from the coaxially aligned blades 14 and 22 may be used for displaying the image.

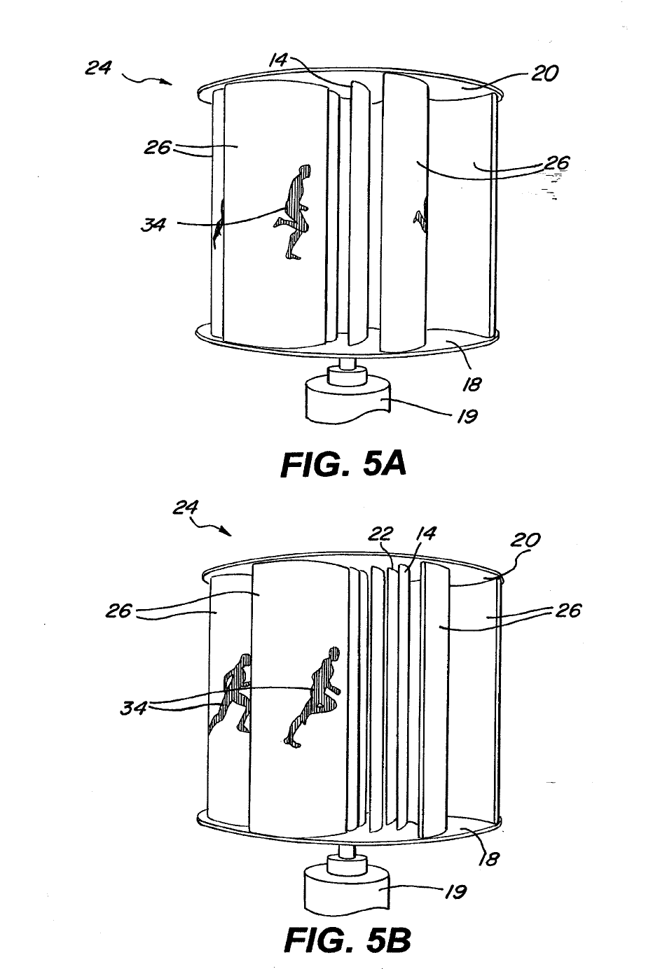

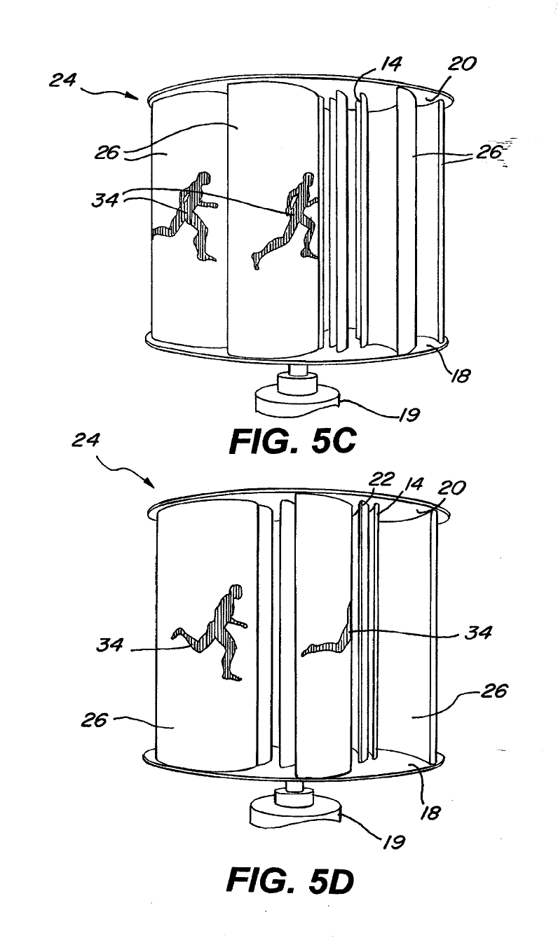

FIGS. 4A-4D illustrate different frame views of one or more images 30 displayed on the wind turbine 10 of FIG. 1, and FIGS. 5A-5D illustrate different frame views of one or more images 34 displayed on the wind turbine 24 of FIG. 3, according to embodiments of the present disclosure. As can be appreciated, there may be at least two image frames, each having one or more images 30, to provide a dynamic image effect when viewed in sequence. FIGS. 4A-4D and 5A-5D illustrate four exemplary image frames of a running man in sequence. The one or more images may be displayed on at least two blades and appear dynamic with the rotation of the blades around the central axis of rotation 13. To generate this dynamic image effect, images 30 may be applied in a predetermined pattern on the blades 14, for each image frame, to appear dynamic with the display of each image frame, in sequence, via the rotation of the blades 14. The image 30 may be displayed across two or more of blades 14. Alternatively, as shown in FIGS. 5A-5D, the image 34 may be completely displayed on one blade 26. To generate a dynamic image effect, one or more blades 26 may each display the image frame with image 34 in a predetermined pattern to appear dynamic with the display of each image frame, in sequence, via the rotation of the blades 26. The predetermined pattern may be a slight change in the shape of the image from the image displayed in the prior and/or post image frame, such that with the rotation of the turbine, a dynamic image effect appears to the naked eye.

As can be appreciated, the appearance of a dynamic image may be used to catch the attention of nearby individuals. Various colors, designs, and inks may be used for the image. In one embodiment, the image may include an advertisement and/or a pattern for calling a consumer's attention to a product or service, for example, a company logo or a product image.

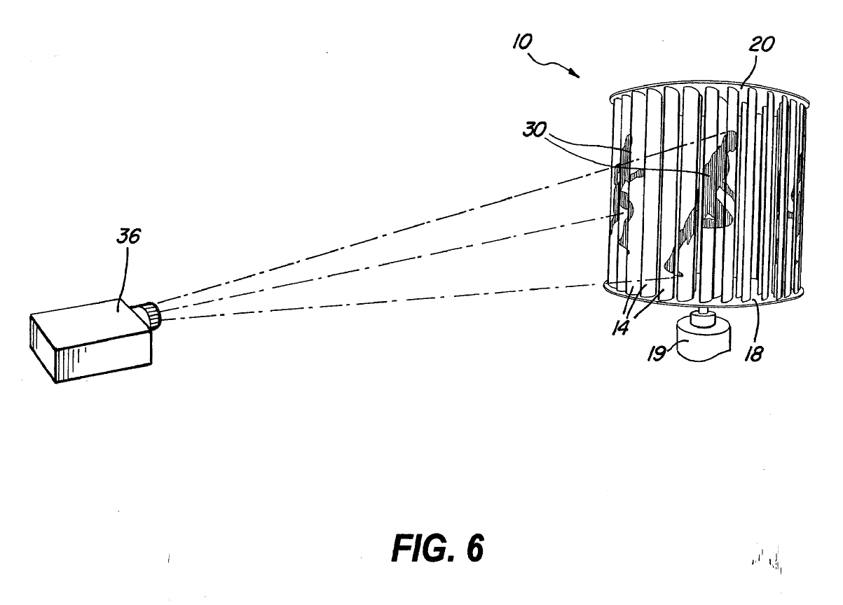

The image can be displayed on one or more blades by printing, imprinting, typing or coupling the image onto the one or more blades. Other methods known to a person skilled in the art may also be used to display and/or apply the image on the one or more blades. For example, the image may be coupled by means of an adhesive or other attachment means known to a person skilled in the art. In one embodiment, the image may be displayed on the one or more blades by projecting a light projection beam of the image from a projector 36, as shown in FIG. 6.

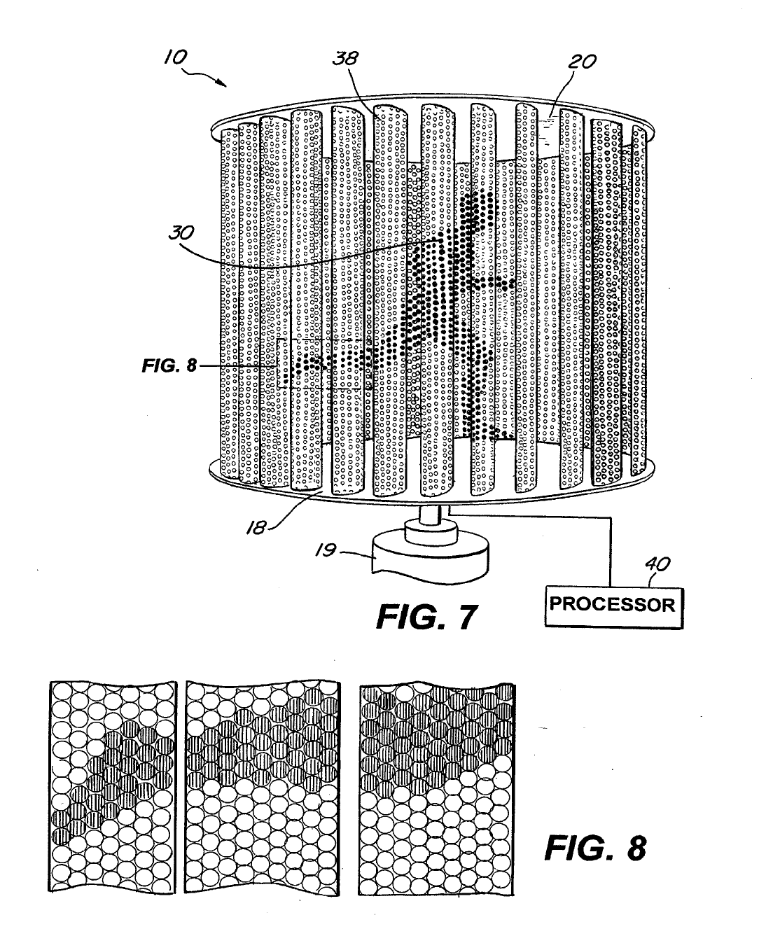

According to one embodiment, the image may be displayed on the one or more blades using an array of light sources coupled to the one or more blades. FIG. 7 illustrates the wind turbine of FIG. 1 with an image 30 displayed on one or more blades 14 using an array of light bulbs 38, such as LED lights, according to an embodiment of the present disclosure. The array of light bulbs 38 may be coupled to the wind rotor 12 and/or the blades 14. The light bulbs 38 may be triggered to light at a certain time and/or location as the wind turbine 10 rotates around the central axis of rotation 13. For example, the light bulbs 38 may be triggered to light on and off using a programmable chip (not shown) or a machine-readable medium with code instructions, which when read by a processor 40, may cause the light bulbs 38 to turn on or off. The processor 40 may be coupled to the light bulbs 38 to control the on and off switching. Alternatively, the processor 40 may wirelessly transmit to a receiver or transceiver (not shown), coupled to the light bulbs 38, to control the on and off switching.

By selectively turning some light bulbs 38 on while others are turned off, an image 30 may be displayed on the blades 14. FIG. 8 is an enlarged view of section 8 of FIG. 7, illustrating an image with some light bulbs 38 turned on while other light bulbs 38 are turned off. The image 30 may appear dynamic as the blades 14 rotates, or static, despite the rotation of the blades 14, for example, by programming the light bulbs 38 to sequentially turn on and off at the same speed at which the wind turbine 10 rotates. As is understood by persons skilled in the art, other light sources for displaying the image may be used, for example, but not limited to, LCD display panels and plasma display panels.

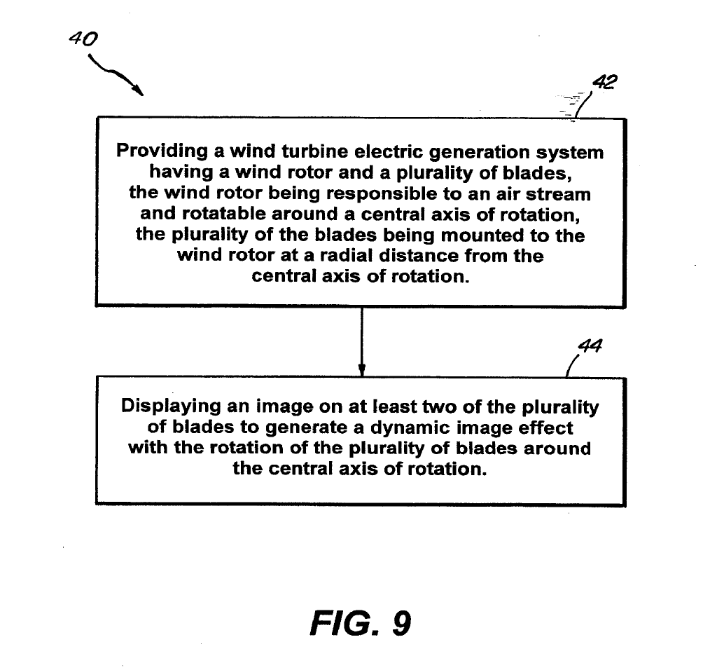

FIG. 9 illustrates an exemplary flowchart 40 outlining a method for providing a dynamic image effect on a renewable energy apparatus, according to an embodiment of the present disclosure. The method may include providing a wind turbine electric generation system having a wind rotor and a plurality of blades, as discussed above (42). The wind rotor being responsive to an air stream and rotatable around a central axis of rotation, with the plurality of blades being mounted to the wind rotor at a radial distance from the central axis of rotation. Next, displaying an image on at least two of the plurality of blades to generate a dynamic image effect with the rotation of the plurality of blades around the central axis of rotation (44).

As discussed above, the image may be displayed on at least two of the plurality of blades by printing, imprinting, typing, coupling the image onto the one or more blades. The image may also be displayed on the one or more blades by projecting a light projection beam of the image or by selectively switching on and off an array of light bulbs 38 coupled to the blades.

As can be appreciated by a person skilled in the art, the wind turbine may not only generate revenue by producing electricity from wind, but also generate revenue from advertising space available on the blades of the wind turbine.

The embodiments of the present disclosure are not limited to wind turbine electric generation systems or wind turbines but can also be used with any other renewable energy product. For example, solar panels (not shown) may also have an advertisement applied to the surface of the panel. A static or dynamic image of, for example, an advertisement, may be translucent or transparent to allow light to pass through the solar panels. The light may then be captured and converted to electricity by photovoltaic effect. As can be appreciated by a person skilled in the art, the solar panels (not shown) may not only generate revenue by producing electricity from light, but also generate revenue from advertising space available on the outer surface of the solar panels.

In this description, various functions and operations may be described as being performed by or caused by software code to simplify description. However, those skilled in the art will recognize that what is meant by such expressions is that the functions result from execution of the code/instructions by a processor, such as a microprocessor. Alternatively, or in combination, the functions and operations can be implemented using special purpose circuitry, with or without software instructions, such as using Application-Specific Integrated Circuit (ASIC) or Field-Programmable Gate Array (FPGA). Embodiments can be implemented using hardwired circuitry without software instructions, or in combination with software instructions. Thus, the techniques are limited neither to any specific combination of hardware circuitry and software, nor to any particular source for the instructions executed by the data processing system. While some embodiments can be implemented in fully functioning computers and computer systems, various embodiments are capable of being distributed as a computing product in a variety of forms and are capable of being applied regardless of the particular type of machine or computer-readable media used to actually effect the distribution.

At least some aspects disclosed can be embodied, at least in part, in software. That is, the techniques may be carried out in a computer system or other data processing system in response to its processor, such as a microprocessor, executing sequences of instructions contained in a memory, such as ROM, volatile RAM, non-volatile memory, cache or a remote storage device.

Routines executed to implement the embodiments may be implemented as part of an operating system or a specific application, component, program, object, module or sequence of instructions referred to as “computer programs.” The computer programs typically include one or more instructions set at various times in various memory and storage devices in a computer, and that, when read and executed by one or more processors in a computer, cause the computer to perform operations necessary to execute elements involving the various aspects.

A machine readable medium can be used to store software and data which when executed by a data processing system causes the system to perform various methods. The executable software and data may be stored in various places including for example ROM, volatile RAM, non-volatile memory and/or cache. Portions of this software and/or data may be stored in any one of these storage devices. Further, the data and instructions can be obtained from centralized servers or peer to peer networks. Different portions of the data and instructions can be obtained from different centralized servers and/or peer to peer networks at different times and in different communication sessions or in a same communication session. The data and instructions can be obtained in entirety prior to the execution of the applications. Alternatively, portions of the data and instructions can be obtained dynamically, just in time, when needed for execution. Thus, it is not required that the data and instructions be on a machine readable medium in entirety at a particular instance of time. Examples of computer-readable media include but are not limited to recordable and non-recordable type media such as volatile and non-volatile memory devices, read only memory (ROM), random access memory (RAM), flash memory devices, floppy and other removable disks, magnetic disk storage media, optical storage media (e.g., Compact Disk Read-Only Memory (CD ROMS), Digital Versatile Disks (DVDs), etc.), among others.

The computer-readable media may store the instructions. In general, a tangible machine readable medium includes any mechanism that provides (i.e., stores and/or transmits) information in a form accessible by a machine (e.g., a computer, network device, personal digital assistant, manufacturing tool, any device with a set of one or more processors, etc.).

In various embodiments, hardwired circuitry may be used in combination with software instructions to implement the techniques. Thus, the techniques are neither limited to any specific combination of hardware circuitry and software nor to any particular source for the instructions executed by the data processing system. Although some of the drawings illustrate a number of operations in a particular order, operations which are not order dependent may be reordered and other operations may be combined or broken out. While some reordering or other groupings are specifically mentioned, others will be apparent to those of ordinary skill in the art and so do not present an exhaustive list of alternatives. Moreover, it should be recognized that the stages could be implemented in hardware, firmware, software or any combination thereof.

The disclosure includes methods and apparatuses which perform these methods, including data processing systems which perform these methods, and computer readable media containing instructions which when executed on data processing systems cause the systems to perform these methods.

While the methods and systems have been described in terms of what are presently considered to be the most practical and preferred embodiments, it is to be understood that the disclosure need not be limited to the disclosed embodiments. It is intended to cover various modifications and similar arrangements included within the spirit and scope of the claims, the scope of which should be accorded the broadest interpretation so as to encompass all such modifications and similar structures. The present disclosure includes any and all embodiments of the following claims.

It should also be understood that a variety of changes may be made without departing from the essence of the invention. Such changes are also implicitly included in the description. They still fall within the scope of this invention. It should be understood that this disclosure is intended to yield a patent covering numerous aspects of the invention both independently and as an overall system and in both method and apparatus modes. For example, although the figures illustrate a vertical axis wind turbine, the turbine may have any configuration or alignment without departing from the essence of the invention. For instance, the turbine may have a horizontal axis. Additionally, while the turbine described is used to harness wind energy, the turbine may be used to harness energy from any fluid flow, such as water flow.

Further, each of the various elements of the invention and claims may also be achieved in a variety of manners. This disclosure should be understood to encompass each such variation, be it a variation of an embodiment of any apparatus embodiment, a method or process embodiment, or even merely a variation of any element of these.

Particularly, it should be understood that as the disclosure relates to elements of the invention, the words for each element may be expressed by equivalent apparatus terms or method terms—even if only the function or result is the same.

Such equivalent, broader, or even more generic terms should be considered to be encompassed in the description of each element or action. Such terms can be substituted where desired to make explicit the implicitly broad coverage to which this invention is entitled.

It should be understood that all actions may be expressed as a means for taking that action or as an element which causes that action.

Similarly, each physical element disclosed should be understood to encompass a disclosure of the action which that physical element facilitates.

In this regard it should be understood that for practical reasons and so as to avoid adding potentially hundreds of claims, the applicant has presented claims with initial dependencies only.

To the extent that insubstantial substitutes are made, to the extent that the applicant did not in fact draft any claim so as to literally encompass any particular embodiment, and to the extent otherwise applicable, the applicant should not be understood to have in any way intended to or actually relinquished such coverage as the applicant simply may not have been able to anticipate all eventualities; one skilled in the art, should not be reasonably expected to have drafted a claim that would have literally encompassed such alternative embodiments.

Further, the use of the transitional phrase “comprising” is used to maintain the “open-end” claims herein, according to traditional claim interpretation. Thus, unless the context requires otherwise, it should be understood that the term “compromise” or variations such as “comprises” or “comprising”, are intended to imply the inclusion of a stated element or step or group of elements or steps but not the exclusion of any other element or step or group of elements or steps.

Such terms should be interpreted in their most expansive forms so as to afford the applicant the broadest coverage legally permissible.

1. A wind turbine electric generation system, comprising:
a wind rotor responsive to an air stream and rotatable around a central axis of rotation,
a plurality of blades mounted to the wind rotor at a radial distance from the central axis of rotation;
an electronic display unit coupled to an outer surface of at least one of the plurality of blades to display an image;
a processor communicatively coupled to the electronic display unit and programmed to transmit an image for display on the electronic display unit; and
an electric generator coupled to and driven by the wind rotor to generate electricity.

2. The wind turbine electric generation system of claim 1, wherein the electronic display unit is coupled to an outer surface of at least two of the plurality of blades to display the image across the at least two of the plurality of blades.

3. The wind turbine electric generation system of claim 1, wherein the image comprises an advertisement for calling a consumer's attention to a product or service.

4. The wind turbine electric generation system of claim 1, wherein the image comprises a pattern for calling a consumer's attention to a product or service.

5. The wind turbine electric generation system of claim 1, wherein the electronic display unit comprises an array of light bulbs coupled to the plurality of blades, the processor programmed to selectively turn on and off the array of light bulbs for displaying the image on at least one of the plurality of blades.

6. The wind turbine electric generation system of claim 1, wherein the plurality of blades are fabricated from a material selected from a group consisting of a reinforced foam material, a material with fiber reinforced extrusions, a metal skin material, and a plastic foam material with a dip coated skin.

7. The wind turbine electric generation system of claim 1, wherein the plurality of blades are equally spaced from one another.

8. A wind turbine electric generation system, comprising:
a wind rotor responsive to an air stream and rotatable around a central axis of rotation,
a plurality of blades mounted to the wind rotor at a radial distance from the central axis of rotation, each blade having an outer surface;
a first electronic display unit coupled to the outer surface of a first blade, from the plurality of blades, and a second electronic display unit coupled to the outer surface of a second blade, from the plurality of blades;
a processor communicatively coupled to the first and second electronic display units and programmed to display an image sequence on the first and second electronic display units, the displayed images generating a dynamic image effect with the rotation of the plurality of blades around the central axis of rotation; and
an electric generator coupled to and driven by the wind rotor to generate electricity.

9. The wind turbine electric generation system of claim 8, wherein each image comprises a pattern for calling a consumer's attention to a product or service.

10. The wind turbine electric generation system of claim 8, wherein each image comprises an advertisement for calling a consumer's attention to a product or service.

11. The wind turbine electric generation system of claim 8, wherein the each electronic display unit comprises an array of light bulbs coupled to the plurality of blades the processor programmed to selectively turn on and off the array of light bulbs for displaying the image on at least two of the plurality of blades.

12. A method for manufacturing a renewable energy apparatus, the method comprising:
providing a wind turbine electric generation system having a wind rotor and a plurality of blades, the wind rotor being responsive to an air stream and rotatable around a central axis of rotation, the plurality of blades being mounted to the wind rotor at a radial distance from the central axis of rotation;
coupling an electronic display unit to an outer surface of at least one of the plurality of blades to display an image; and
communicatively coupling a processor to the electronic display unit, via a transceiver, to control the display of the image on the electronic display unit.

13. The method of claim 12, further comprising displaying the image across two or more of the plurality of blades.

14. The method of claim 12, wherein the image comprises an advertisement for calling a consumer's attention to a product or service.

15. The method of claim 12, wherein the image comprises a pattern for calling a consumer's attention to a product or service.

16. The method of claim 12, wherein the electronic display unit includes an array of light sources or a display panel coupled to the outer surface of at least one of the plurality to blades.

17. A wind turbine for displaying an image, comprising:
a wind rotor responsive to an air stream and rotatable around a central axis of rotation,
a plurality of blades mounted to the wind rotor at a radial distance from the central axis of rotation;
an electronic display coupled to the plurality of blades; and
a processor communicatively coupled to the electronic display, via a transceiver, and programmed to display the image on at least two of the plurality of blades.
